(19) United States
(12) Patent Application Publication
(10) Pub. No.: US 2015/0021666 A1
(43) Pub. Date: Jan. 22, 2015

(54) TRANSISTOR HAVING PARTIALLY OR WHOLLY REPLACED SUBSTRATE AND METHOD OF MAKING THE SAME

(71) Applicant: TAIWAN SEMICONDUCTOR MANUFACTURING COMPANY., LTD., Hsinchu (TW)

(72) Inventors: Chi-Ming CHEN, Zhubei City (TW); Chih-Wen HSIUNG, Hsinchu City (TW); Yuan-Chih HSIEH, Hsinchu City (TW); Po-Chun LIU, Hsinchu City (TW); Ming Chyi LIU, Hsinchu City (TW); Chung-Yi YU, Hsinchu (TW); Chia-Shiung TSAI, Hsinchu (TW); Xiaomeng CHEN, Hsinchu (TW)

(21) Appl. No.: 13/944,779

(22) Filed: Jul. 17, 2013

(51) Int. Cl. H01L 29/778; H01L 29/66

(52) U.S. Cl. CPC H01L 29/778; H01L 29/66431
USPC 257/194; 438/172

(57) ABSTRACT

A transistor includes a substrate, a channel layer over the substrate, an active structure over the channel layer, a gate electrode over the channel layer, and a drain electrode over the channel layer. The active structure is configured to cause a two dimensional electron gas (2DEG) to be formed in the channel layer along an interface between the channel layer and the active structure. The gate electrode and the drain electrode define a first space therebetween. The substrate has a first portion directly under the first space defined between the gate electrode and the drain electrode, and the first portion has a first electrical conductivity value less than that of intrinsic silicon and a thermal conductivity value greater than that of intrinsic silicon.

### RELATED APPLICATIONS

The instant application is related to the following U.S. patent applications:
U.S. patent application titled “TRANSISTOR HAVING HIGH BREAKDOWN VOLTAGE AND METHOD OF MAKING THE SAME,” attorney docket No. TSMC2013-0481 (T5057-897);
U.S. patent application titled “TRANSISTOR HAVING BACK-BARRIER LAYER AND METHOD OF MAKING THE SAME,” attorney docket No. TSMC2013-0483 (T5057-900);
U.S. patent application titled “TRANSISTOR HAVING DOPED SUBSTRATE AND METHOD OF MAKING THE SAME,” attorney docket No. TSMC2013-0484 (T5057-899);
U.S. patent application titled “TRANSISTOR HAVING A BACK-BARRIER LAYER AND METHOD OF MAKING THE SAME,” attorney docket No. TSMC2013-0485 (T5057-896);
U.S. patent application titled “TRANSISTOR HAVING OHMIC CONTACT BY GRADIENT LAYER AND METHOD OF MAKING SAME” attorney docket no. TSMC2013-0530 (T5057-904);
U.S. patent application titled “TRANSISTOR HAVING AN OHMIC CONTACT BY SCREEN LAYER AND METHOD OF MAKING THE SAME” attorney docket no. TSMC2013-0531 (T5057-902);
U.S. patent application titled “TRANSISTOR HAVING METAL DIFFUSION BARRIER AND METHOD OF MAKING THE SAME” attorney docket no. TSMC2013-0615 (T5057-915); and
U.S. patent application titled “SEMICONDUCTOR DEVICE, HIGH ELECTRON MOBILITY TRANSISTOR (E-HEMT) AND METHOD OF MANUFACTURING,” attorney docket no. TSMC2013-0482 (T5057-895).

The entire contents of the above-referenced applications are incorporated by reference herein.

### BACKGROUND

In semiconductor technology, Group III-Group V (or III-V) semiconductor compounds are used to form various integrated circuit devices, such as high power field-effect transistors, high frequency transistors, high electron mobility transistors (HEMTs), or metal-insulator-semiconductor field-effect transistors (MISFETs). A HEMT is a field effect transistor incorporating a junction between two materials with different band gaps (i.e., a heterojunction) as the channel instead of a doped region, as is generally the case for metal oxide semiconductor field effect transistors (MOSFETs). In contrast with MOSFETs, HEMTs have a number of attractive properties including high electron mobility and the ability to transmit signals at high frequencies, etc.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. It is emphasized that, in accordance with standard practice in the industry various features may not be drawn to scale and are used for illustration purposes only. In fact, the dimensions of the various features in the drawings may be arbitrarily increased or reduced for clarity of discussion.

FIG. 1A is a cross-sectional view of a high electron mobility transistor (HEMT) having a partially replaced substrate in accordance with one or more embodiments.

FIG. 1B is a cross-sectional view of an HEMT having a wholly replaced substrate in accordance with one or more embodiments.

FIG. 2 is a flow chart of a method of making an HEMT having a partially replaced substrate in accordance with one or more embodiments.

FIGS. 3A-3G are cross-sectional views of an HEMT having a partially replaced substrate at various stages of production in accordance with one or more embodiments.

FIG. 4 is a flow chart of another method of making an HEMT having a wholly replaced substrate in accordance with one or more embodiments.

FIGS. 5A-5C are cross-sectional views of a HEMT having a wholly replaced substrate at various stages of production in accordance with one or more embodiments.

### DETAILED DESCRIPTION

The following disclosure provides many different embodiments, or examples, for implementing different features of the invention. Specific examples of components and arrangements are described below to simplify the present disclosure. These are examples and are not intended to be limiting.

Moreover, spatially relative terms, for example, “lower,” “upper,” “horizontal,” “vertical,” “above,” “below,” “up,” “down,” “top,” “bottom,” “left,” “right,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

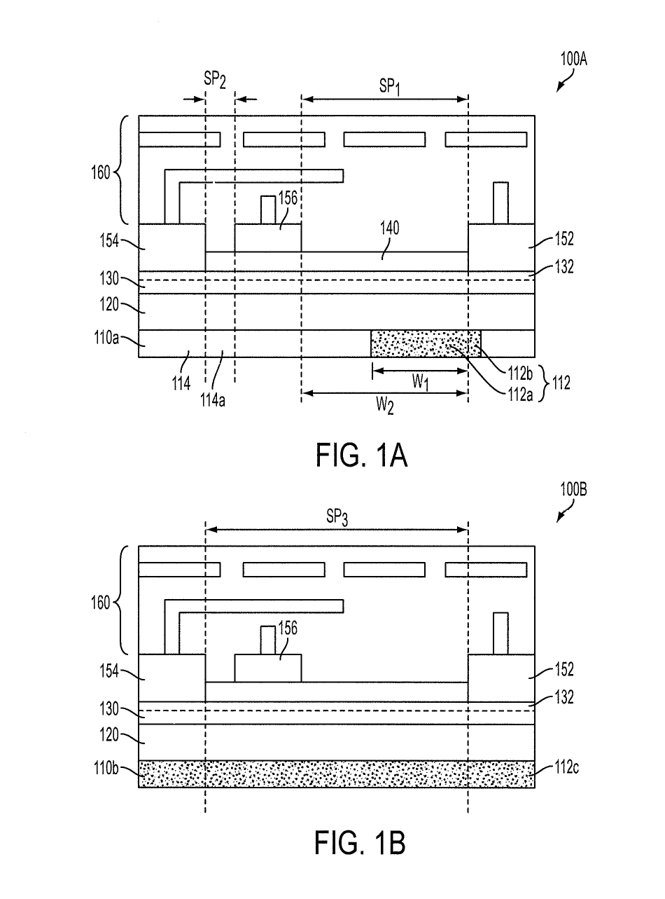

FIG. 1A is a cross-sectional view of a high electron mobility transistor (HEMT) 100A in accordance with one or more embodiments. Only HEMT 100A is depicted in FIG. 1A. One or more other electrical components that belong to the same integrated circuit as the HEMT 100A are omitted. HEMT 100A includes a substrate 110a, a buffer layer 120 over the substrate 110a, a channel layer 130 over the buffer layer 130, an active structure 140 over the channel layer 130, electrodes 152, 154, and 156 over the channel layer 130, and an interconnection structure 160 over the active structure 140.

Active structure 140 and channel layer 130 form a heterojunction therebewteen. Due to a band gap discontinuity between the channel layer 130 and active structure 140, a two dimension electron gas (2-DEG) 132 is formed in the channel layer 130 near an interface with the active structure 140. Drain electrode 152 and source electrode 154 are over the channel layer 130, and a gate electrode 156 is over active structure 156 between the drain and source electrodes 152 and 154.

In some embodiments, buffer layer 120 includes multiple layers, such as seed layers, nucleation layers, and/or graded layers. Buffer layer 120 helps to compensate for a mismatch in lattice structures between substrate 110a and channel layer 130.

In some embodiments, buffer layer 120 includes a nucleation layer having a first layer of AlN and a second layer of AlN over the first layer of AlN. In at least one embodiment, the buffer layer 120 includes a graded layer having aluminum gallium nitride (AlₓGa₁₋ₓN). X is the aluminum content ratio in the graded layer. In some embodiments, the graded layer includes multiple layers each having a decreased ratio X from the bottom to the top portions of the graded layer. In at least one embodiment, the graded aluminum gallium nitride layer has three layers whose ratios X are 0.9˜0.7, 0.6˜0.4, and 0.3˜0.15, from the bottom to the top. In some embodiments, instead of having multiple layers, the graded layer has a continuous gradient of the X value. In some embodiments, X ranges from about 0.9 to about 0.15. In some embodiments, graded layer has a thickness ranging from about 50 nm to about 250 nm. In some embodiments, nucleation layer is omitted, and graded layer is directly on substrate 110a.

The substrate 110a includes a replacement portion 112 and a remaining portion 114. In some embodiments, replacement portion 112 includes a first portion 112a directly under a space SP₁ defined between electrode 152 and electrode 156 and a second portion 112b directly under electrode 152. In some embodiments, portion 112a has an electrical conductivity value less than that of intrinsic silicon and a thermal conductivity value greater than that of intrinsic silicon. In some embodiments, along a direction defined by electrode 156 and electrode 152, a ratio of a width W₁ of portion 112a of the substrate to a width W₂ of the space SP₁ ranges from 10% to 100%. In at least one embodiment, portions 112a and 112b form an integrated member (i.e., replacement portion 112) and have the same material. In some embodiments, portion 112b extends throughout an entire section of the substrate 110a that is directly under the electrode 152. In some embodiments, portion 112a, or the entire replacement portion 112, of the substrate includes aluminum nitride (AlN) or silicon carbide (SiC).

In some embodiments, remaining portion 114 includes silicon carbide (SiC), sapphire, or another suitable substrate material. In some embodiments, remaining portion 114 is a silicon substrate having a (111) lattice structure. Portion 114 include portion 114a directly under a space SP₂ defined between electrode 154 and electrode 156, and portion 114a has an electrical conductivity value greater than that of portion 112a.

In some embodiments, buffer layer 120 and the remaining portion 114 of substrate 110a also constitute a heterojunction. As a result, an unintended electron layer is formed in the remaining portion 114 near the interface between the remaining portion 114 and the buffer layer 120. This unintended electron layer is sometimes referred to as “inversion electron.” In a configuration that does not have the replacement portion 112, the “inversion electron” provides a low resistance leakage path between the drain electrode 152 and the source electrode 154 through the substrate. The inclusion of the replacement portion 112 interrupts the continuity of electrical path formed by the “inversion electron.” As a result, the leakage path through the substrate formed by “inversion electron” is reduced or illuminated. In addition, because replacement portion 112 has thermal conductivity value greater than that of intrinsic silicon, the replacement portion 112 does not degrade the thermal dissipation characteristic of the integrated circuit on which the HEMT 100A is formed.

HEMT 100A is illustrated as a non-limiting example, and the partially replaced substrate 110a is applicable to other electrical devices or other types of transistors.

Channel layer 130 is used to help form a conductive path for selectively connecting electrodes 152 and 154. In some embodiments, channel layer 130 includes gallium nitride (GaN). In some embodiments, channel layer 130 is an un-doped layer or has a p-type dopant concentration of equal to or less than 1×10¹⁷ ions/cm³. In some embodiments, channel layer 130 is an undoped layer or an unintentionally doped layer. In some embodiments, channel layer 130 has a thickness ranging from about 0.5 μm to about 5 μm. If a thickness of channel layer 130 is too thin, channel layer 130 will not provide sufficient charge carriers to allow HEMT 100A to function properly. If the thickness of channel layer 130 is too great, material is wasted and production costs increase. In some embodiments, channel layer 130 is formed by an epitaxial process. In some embodiments, channel layer 130 is formed at a temperature ranging from about 1000° C. to about 1200° C.

Interconnection structure 160 includes conductive lines usable to provide electrical paths between the transistor 100A and one or more other electrical components formed on the substrate 110a. In some embodiments, interconnection structure 160 includes layers of conductive lines, via plugs, and interlayer dielectric materials. In some embodiments, the conductive lines and via plugs in interconnection structure is formed by dual damascene processes.

FIG. 1B is a cross-sectional view of another HEMT 100B having a wholly replaced substrate 110b in accordance with one or more embodiments. Compared with the HEMT 100A, similar components are given similar reference numerals, and the detailed description thereof is not repeated. In addition, electrodes 152 and 154 define a space SP₃ therebetween, and a replacement portion 112c of substrate 110b of HEMT 100B extends throughout an entire section of the substrate 110b under the space SP₃, the drain electrode 152, and the source electrode 154. In some embodiments, portion 112c has an electrical conductivity value less than that of intrinsic silicon and a thermal conductivity value greater than that of intrinsic silicon. In some embodiments, replacement portion 112c of the substrate includes aluminum nitride (AlN) or silicon carbide (SiC). In some embodiments, the term “wholly replaced substrate” refers to the replacement portion 112c occupying an entire section under the transistor 100B but not necessarily the entire substrate 110b of the integrated circuit on which the HEMT 100B is formed. In some embodiments, the replacement portion 112c occupies the entire substrate 110b of the integrated circuit on which the HEMT 100B is formed.

In some embodiments, the remaining portion 114 (FIG. 1A) is completely removed and replaced by replacement portion 112c. As a result, no or less conductive “electron inversion” is formed as a result of the junction between replacement portion 112c and buffer layer 120. Thus, the leakage path through the substrate formed by “inversion electron” is reduced or illuminated. In addition, because replacement portion 112c has thermal conductivity value greater than that of intrinsic silicon, the replacement portion 112c does not degrade the thermal dissipation characteristic of the integrated circuit on which the HEMT 100B is formed.

HEMT 100B is illustrated as a non-limiting example, and the wholly replaced substrate 110b is applicable to other electrical devices or other types of transistors.

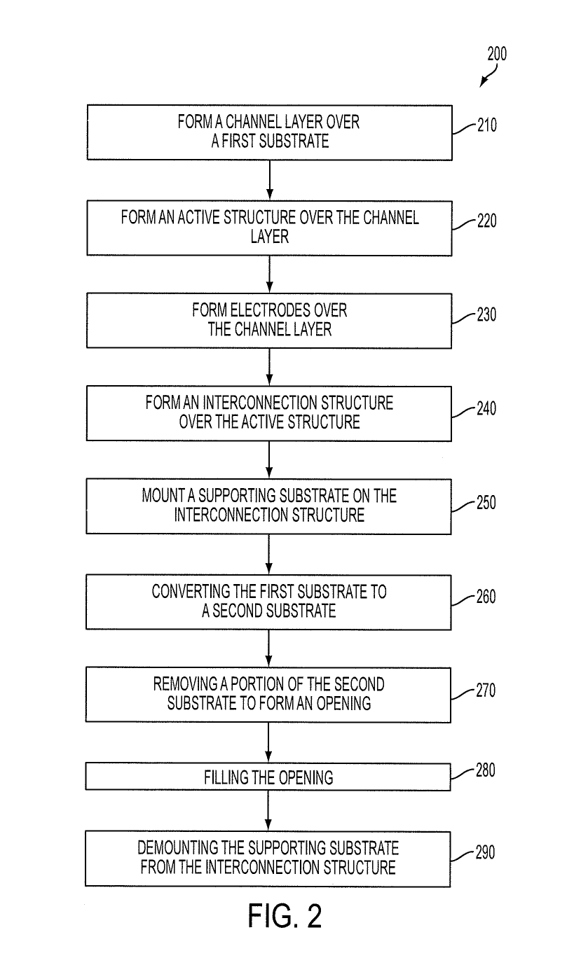

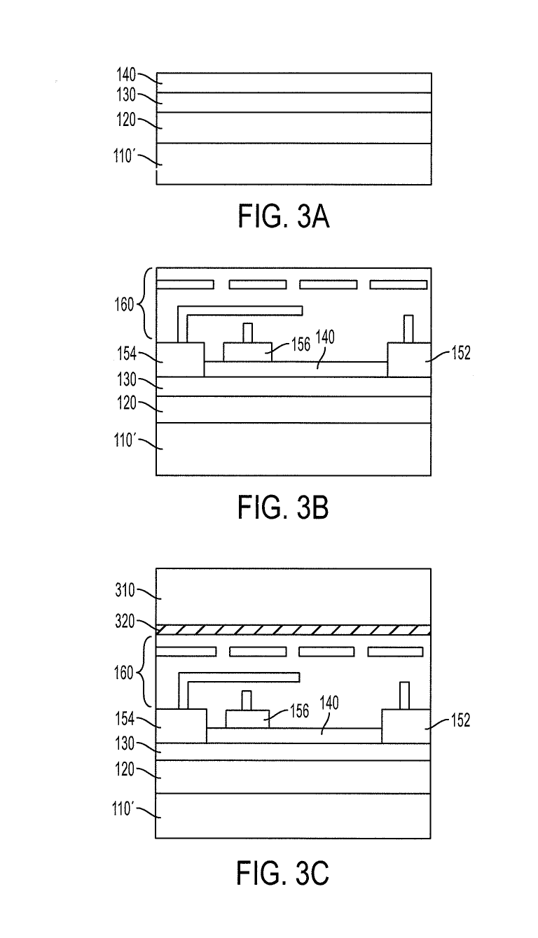

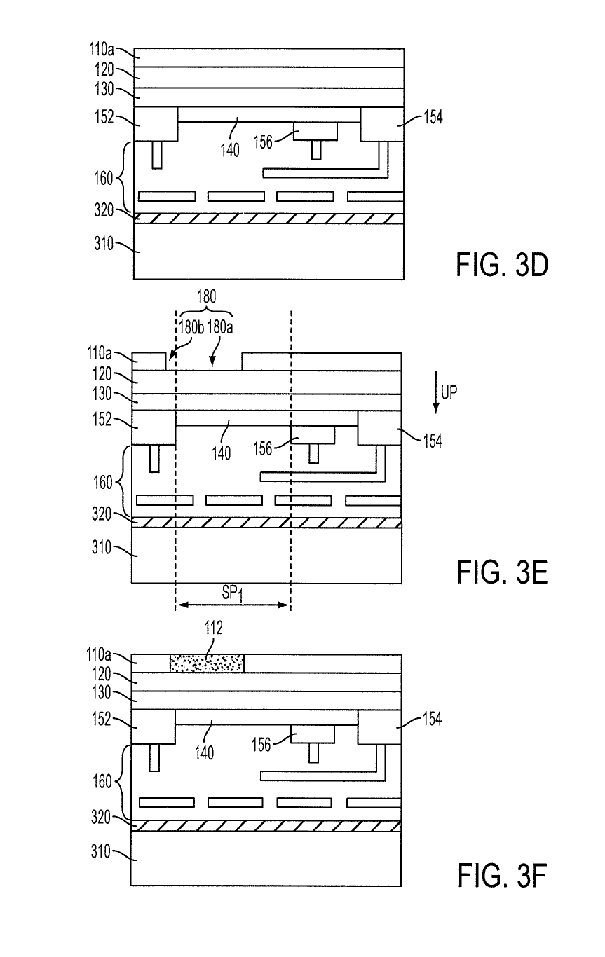

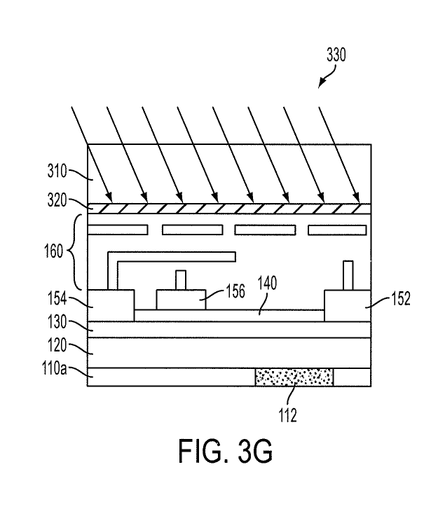

FIG. 2 is a flow chart of a method 200 of making an HEMT in accordance with one or more embodiments. FIGS. 3A-3G are cross-sectional views of an HEMT at various stages of production in accordance with one or more embodiments. It is understood that additional operations may be performed before, during, and/or after the method 200 depicted in FIG. 2, and that some other processes may only be briefly described herein.

Method 200 begins with operation 210 in which a channel layer is formed over a first substrate and over a buffer layer. In some embodiments, the channel layer includes p-type dopants. In some embodiments, the channel layer includes GaN, and the P-type doping is implemented by using dopants including carbon, iron, magnesium, zinc or other suitable p-type dopants. In some embodiments, the channel layer is formed by performing an epitaxial process. In some embodiments, the epitaxial process includes a metal-organic chemical vapor deposition (MOCVD) process, a molecular beam epitaxy (MBE) process, a hydride vapor phase epitaxy (HVPE) process or another suitable epitaxial process. In some embodiments, the channel layer has a thickness ranging from about 0.5 μm to about 5 μm. In some embodiments, the dopant concentration in the channel layer is equal to or less than about 1×10¹⁷ ions/cm³. In some embodiments, the channel layer is an undoped layer or an unintentionally doped layer. In some embodiments, the channel layer is formed at a temperature ranging from about 1000° C. to about 1200° C.

In operation 220 an active structure is formed over the channel layer. In some embodiments, the active layer includes one or more layers of AlN, AlₓGa₁₋ₓN, combinations thereof, or other suitable materials. In some embodiments, x ranges from about 0.1 to about 0.3. In some embodiments, the active layer is formed by performing an epitaxial process. In some embodiments, the epitaxial process includes a MOCVD process, a MBE process, a HVPE process or another suitable epitaxial process. In some embodiments, the active layer has a thickness ranging from about 10 nm to about 40 nm. In some embodiments where the active layer includes both AlN and AlₓGa₁₋ₓN, the AlN layer has a thickness ranging from about 0.5 nm to about 1.5 nm and the AlₓGa₁₋ₓN layer has a thickness ranging from about 10 nm to about 40 nm. In some embodiments, the active layer is formed at a temperature ranging from about 1000° C. to about 1200° C.

FIG. 3A is a cross-sectional view of a HEMT following operation 220 in accordance with one or more embodiments. The HEMT includes buffer layer 120 over a first substrate 110′, a channel layer 120 over the buffer layer 130, and an active structure 140 over the channel layer.

Returning to FIG. 2, in operation 230 electrodes, such as a drain electrode, a source electrode, and a gate electrode, are formed over the channel layer. In some embodiments, the drain electrode and the source electrode are formed over or partially buried in the channel layer, and the gate electrode is formed over the active layer. In some embodiments, a patterned mask layer (i.e., a photoresistive layer) is formed on the upper surface of the active layer, and an etching process is performed to remove a portion of the active layer to form openings partially exposing an upper surface of the channel layer. A metal layer is then deposited over the patterned active layer and fills the openings and contacts the channel layer. Another patterned photoresist layer is formed over the metal layer, and the metal layer is etched to form the source or drain electrodes over the openings and the gate electrode over the upper surface of the active layer. In some embodiments, the metal layer for forming the electrodes includes one or more conductive materials. In some embodiments, the electrodes include one or more layers of conductive materials. In at least one embodiment, the electrodes include at least one barrier layer contacting the channel layer and/or the active layer.

In operation 240 an interconnection structure is formed over the electrodes, such as a drain electrode, a source electrode, and a gate electrode, and the active structure.

FIG. 3B is a cross-sectional view of a HEMT following operation 240 in accordance with one or more embodiments. The HEMT further includes drain electrode 152 over the channel layer 130, source electrode 154 over the channel layer 130, gate electrode 156 over the channel layer 130 and active structure 140, and an interconnect structure 160 over the active structure 160 and the electrodes 152, 154, and 156.

Returning to FIG. 2, in operation 250, a supporting substrate is mounted on the interconnection structure. In some embodiments, the supporting substrate is a silicon substrate, an aluminum oxide (Al₂O₃) substrate, a glass substrate, a quartz substrate, or a sapphire substrate. In at least one embodiment, the supporting substrate is a silicon (100) substrate. In some embodiments, prior to mounting the supporting substrate to the interconnection structure, a layer of adhesive material is coated on the supporting substrate. In some embodiments, operation 250 includes bonding the supporting substrate to the interconnection structure by the adhesive layer. In some embodiments, operation 250 further includes applying an electromagnetic wave, such as ultraviolet light, on the adhesive layer in order to cure the adhesive layer.

FIG. 3C is a cross-sectional view of a HEMT following operation 250 in accordance with one or more embodiments. The HEMT further includes a supporting substrate 310 over the interconnection structure 160 and an adhesive layer 320 bonding the interconnection structure 160 and the supporting substrate 310.

Returning to FIG. 2, in operation 260, the resulting structure as depicted in FIG. 3C is flipped up-side-down, and the first substrate is converted to a second substrate, which has a thickness less than that of the first substrate. In some embodiments, operation 260 includes performing a wafer backside grinding process to reduce a thickness of the substrate from about 800˜1000 micrometers (μm) to a thickness ranging from 50 μm to 400 μm. In some embodiments, the conversion is performed by other applicable wafer thinning processes.

FIG. 3D is a cross-sectional view of a HEMT following operation 260 in accordance with one or more embodiments. The first substrate 110′ of the HEMT is thinned to become a second substrate 110a.

Returning to FIG. 2, in operation 270, a portion of the second substrate is removed to form an opening. A portion of the opening is directly under (viewed according to an orientation that the interconnection is over the channel layer) a space defined between the gate electrode and the drain electrode. In some embodiments, the opening is also directly under (viewed according to an orientation that the interconnection is over the channel layer) the drain electrode. In some embodiments, operation 270 includes performing a dry etch, a wet etch, or a combination thereof, to partially remove the second substrate. In some embodiments, the critical dimension of the etch process performed in operation 270 is no greater than 8˜20 μm. In some embodiments, a ratio of a width of the portion of the opening directly under the space defined between the gate electrode and the drain electrode and a width of the space ranges from 10% to 100%.

FIG. 3E is a cross-sectional view of a HEMT following operation 270 in accordance with one or more embodiments. A portion of the second substrate 110a is removed to form an opening 180. The opening 180 including a first portion 180a directly under (viewed according to an orientation consistent with the arrow “UP”) the space SP₁ defined between electrodes 154 and 156 and a second portion 180b directly under (viewed according to an orientation consistent with the arrow “UP”) the electrode 152. In some embodiments, a ratio of a width of the first portion 180a of the substrate to a width of the first space SP₁ ranges from 10% to 100%.

Returning to FIG. 2, in operation 280, the opening is filled with a material having an electrical conductivity value lower than that of intrinsic silicon and a thermal conductivity value greater than that of intrinsic silicon. In some embodiments, the material for filling the opening includes AN or SiC. In some embodiments, the filling the opening includes performing a spin-coating process, a plasma-enhanced chemical vapor deposition (PECVD) process, a sputtering process, or an electroplating process.

FIG. 3F is a cross-sectional view of a HEMT following operation 280 in accordance with one or more embodiments. The opening 180 depicted in FIG. 3E is filled to become replacement portion 112 of the substrate 110a. The replacement portion 112 of the substrate has an electrical conductivity value lower than that of intrinsic silicon and a thermal conductivity value greater than that of intrinsic silicon.

Returning to FIG. 2, in operation 290, the resulting structure depicted in FIG. 3F is flipped back to have the substrate 110a at the bottom. In operation 290, the supporting substrate is demounted from the interconnection structure after the filling the opening. In some embodiments, the demounting the supporting substrate includes applying Yttrium Aluminum Garnet laser on the adhesive layer that bonds the interconnection structure and the supporting substrate.

FIG. 3G is a cross-sectional view of a HEMT during the performance of operation 290 in accordance with one or more embodiments. Yttrium Aluminum Garnet laser 330 is applied to the adhesive layer 320 in order to demount the supporting substrate 310 from the interconnection structure 160.

Following operation 290 the HEMT has a similar structure to HEMT 100A.

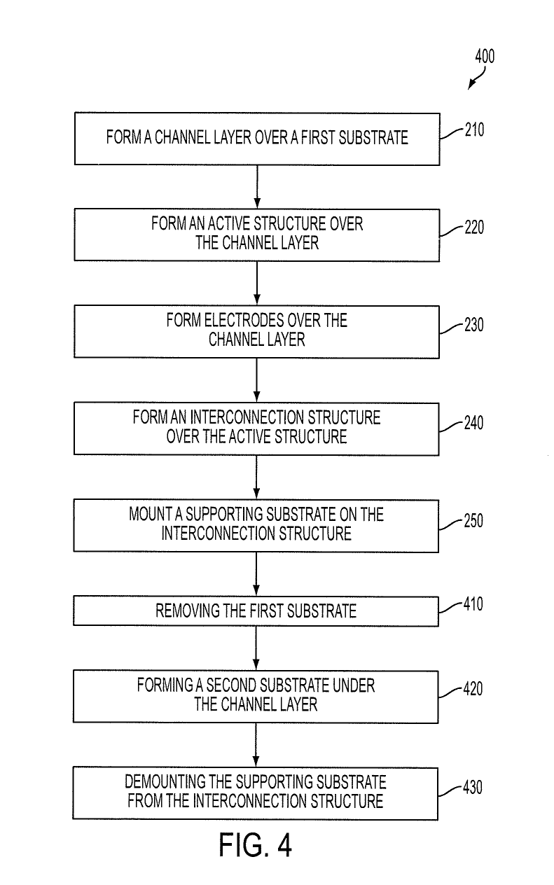

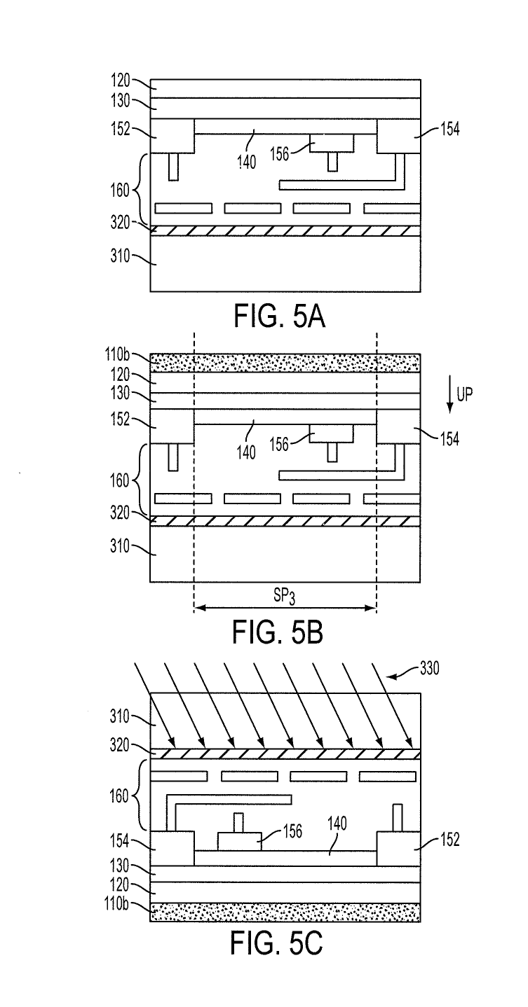

FIG. 4 is a flow chart of a method 400 of making an HEMT in accordance with one or more embodiments. FIGS. 5A-5G are cross-sectional views of an HEMT at various stages of production in accordance with one or more embodiments. It is understood that additional operations may be performed before, during, and/or after the method 400 depicted in FIG. 4, and that some other processes may only be briefly described herein.

Method 400 includes operations 210-250 that are the same or similar to operations 210-250 explained in conjunction with FIG. 2 and FIGS. 3A-3C. Therefore, details regarding operations 210-250 of method 400 are not repeated.

As depicted in FIG. 4, in operation 410, the resulting structure as depicted in FIG. 3C is flipped up-side-down, and the first substrate is removed. In some embodiments, an entire first substrate of the integrated circuit on which the HEMT is formed is removed. In some embodiments, operation 410 includes performing a wafer backside grinding process to substantially remove the entire first substrate. In some embodiments, only a portion of an entire first substrate of the integrated circuit on which the HEMT is formed is removed.

FIG. 5A is a cross-sectional view of a HEMT following operation 410 in accordance with one or more embodiments. The first substrate 110′ of the HEMT is removed.

Returning to FIG. 4, in operation 420, a second substrate is formed under (viewed according to an orientation that the interconnection is over the channel layer) the channel layer. In some embodiments, at least a portion of the second substrate is directly under the drain electrode, the source electrode, and a space defined between the drain electrode and the source electrode. In some embodiments, the portion of the second substrate includes a material having an electrical conductivity value lower than that of intrinsic silicon and a thermal conductivity value greater than that of intrinsic silicon. In some embodiments, the material for forming the portion of the second substrate includes AN or SiC. In some embodiments, the second substrate is formed by performing a spin-coating process, a PECVD process, a sputtering process, or an electroplating process.

FIG. 5B is a cross-sectional view of a HEMT following operation 420 in accordance with one or more embodiments. The substrate 110′ is replaced by substrate 110b. At least a portion 112c of the substrate 110b directly under the drain electrode, the source electrode, and a space SP₃ defined between the drain electrode 152 and the source electrode 154 has an electrical conductivity value lower than that of intrinsic silicon and a thermal conductivity value greater than that of intrinsic silicon.

Returning to FIG. 4, in operation 430, the resulting structure depicted in FIG. 5B is flipped back to have the substrate 110b at the bottom. In operation 430, the supporting substrate is demounted from the interconnection structure after the filling the opening. In some embodiments, the demounting the supporting substrate includes applying Yttrium Aluminum Garnet laser on the adhesive layer that bonds the interconnection structure and the supporting substrate.

FIG. 5C is a cross-sectional view of a HEMT during the performance of operation 430 in accordance with one or more embodiments. Yttrium Aluminum Garnet laser 330 is applied to the adhesive layer 320 in order to demount the supporting substrate 310 from the interconnection structure 160.

Following operation 430 the HEMT has a similar structure to HEMT 100B.

One aspect of this description relates to a transistor. The transistor includes a substrate, a channel layer over the substrate, an active structure over the channel layer, a gate electrode over the channel layer, and a drain electrode over the channel layer. The active structure is configured to cause a two dimensional electron gas (2DEG) to be formed in the channel layer along an interface between the channel layer and the active structure. The gate electrode and the drain electrode define a first space therebetween. The substrate has a first portion directly under the first space defined between the gate electrode and the drain electrode, and the first portion has a first electrical conductivity value less than that of intrinsic silicon and a thermal conductivity value greater than that of intrinsic silicon.

Another aspect of this description relates to a method of making a transistor. The method includes forming a channel layer over a first substrate having a first thickness. An active structure is formed over the channel layer. The active structure is configured to cause a two dimensional electron gas (2DEG) to be formed in the channel layer along an interface between the channel layer and the active structure. A gate electrode is formed over the channel layer. A drain electrode is formed over the channel layer. The first substrate is converted to a second substrate, and the second substrate has a second thickness less than the first thickness. A portion of the second substrate is removed to form an opening, and the opening is directly under a first space defined between the gate electrode and the drain electrode. The opening is filled with a material having an electrical conductivity value lower than that of intrinsic silicon and a thermal conductivity value greater than that of intrinsic silicon.

Still another aspect of this description relates to a method of making a transistor. The method includes forming a channel layer over a first substrate having a first thickness. An active structure is formed over the channel layer. The active structure is configured to cause a two dimensional electron gas (2DEG) to be formed in the channel layer along an interface between the channel layer and the active structure. A gate electrode is formed over the channel layer. A drain electrode is formed over the channel layer. The first substrate is removed. A second substrate is formed under the channel layer, and the second substrate has an electrical conductivity value lower than that of intrinsic silicon and a thermal conductivity value greater than that of intrinsic silicon.

It will be readily seen by one of ordinary skill in the art that the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1-9. (canceled)

10. A method of forming a transistor, comprising:
forming a channel layer over a first substrate, the first substrate having a first thickness;
forming an active structure over the channel layer, the active structure being configured to cause a two dimensional electron gas (2DEG) to be formed in the channel layer along an interface between the channel layer and the active structure;
forming a gate electrode over the channel layer;
forming a drain electrode over the channel layer;
converting the first substrate to a second substrate, the second substrate having a second thickness less than the first thickness;
removing a portion of the second substrate to form an opening, the opening being directly under a first space defined between the gate electrode and the drain electrode; and
filling the opening with a material having an electrical conductivity value lower than that of intrinsic silicon and a thermal conductivity value greater than that of intrinsic silicon.

11. The method of claim 10, wherein the material comprises aluminum nitride (AlN) or silicon carbide (SiC).

12. The method of claim 10, further comprising:
forming an interconnection structure over the active structure;
mounting a supporting substrate on the interconnection structure prior to the converting the first substrate to the second substrate; and
demounting the supporting substrate from the interconnection structure after the filling the opening.

13. The method of claim 12, wherein the mounting the supporting substrate comprises curing an adhesive layer between the supporting substrate and the interconnection structure by applying ultraviolet light on the adhesive layer.

14. The method of claim 13, wherein the demounting the supporting substrate comprises applying Yttrium Aluminum Garnet laser on the adhesive layer.

15. The method of claim 12, wherein the second thickness ranges from 50 μm to 400 μm.

16-20. (canceled)

21. A method of forming a transistor, the method comprising:
forming a channel layer over a first substrate;
forming an active structure over the channel layer, the active structure being configured to cause a two dimensional electron gas (2DEG) to be formed in the channel layer along an interface between the channel layer and the active structure;
forming a gate electrode over the channel layer;
forming a source electrode over the channel layer;
forming an interconnection structure over the active structure;
mounting a supporting substrate on the interconnection structure; and
removing at least a portion of the first substrate.

22. The method of claim 21, wherein the active structure comprises AlN or AlₓGa₁₋ₓN.

23. The method of claim 21, wherein the channel layer comprises carbon, iron, magnesium, or zinc.

24. The method of claim 21, wherein the channel layer has a p-type dopant concentration of less than or equal to 1×10¹⁷ ions/cm³.

25. The method of claim 21, wherein the channel layer has a thickness ranging from 0.5 μm to 5 μm.

26. The method of claim 21, wherein the channel layer is formed at a temperature ranging from 1000° C. to 1200° C.

27. The method of claim 21, wherein the interconnection structure is formed by a dual damascene process.

28. The method of claim 21, wherein the active structure has a thickness ranging from 10 nm to 40 nm.

29. The method of claim 21, wherein the mounting the supporting substrate comprises curing an adhesive layer between the supporting substrate and the interconnection structure by applying ultraviolet light on the adhesive layer.

30. A method of forming a transistor, the method comprising:
forming a channel layer over a first substrate;
forming an active structure over the channel layer, the active structure being configured to cause a two dimensional electron gas (2DEG) to be formed in the channel layer;
forming a gate electrode over the channel layer;
forming a drain electrode over the channel layer;
forming an interconnection structure over the active structure;
mounting a supporting substrate on the interconnection structure; and
removing at least a portion of the first substrate.

32. The method of claim 30, wherein the active structure comprises AlN or AlₓGa₁₋ₓN.

33. The method of claim 30, wherein the channel layer comprises carbon, iron, magnesium, or zinc.

34. The method of claim 30, wherein the channel layer has a p-type dopant concentration of less than or equal to 1×10¹⁷ ions/cm³.

35. The method of claim 30, wherein the channel layer has a thickness ranging from 0.5 μm to 5 μm.
